(19) United States
(12) Patent Application Publication
(10) Pub. No.: US 2011/0291673 A1
(43) Pub. Date: Dec. 1, 2011

(54) CHEMICAL SENSOR

(75) Inventors: Yoshinori Shibata, Osaka (JP); Masahiro Adachi, Osaka (JP)

(73) Assignee: SHARP KABUSHIKI KAISHA, Osaka-shi, Osaka (JP)

(21) Appl. No.: 13/147,798

(22) PCT Filed: Feb. 8, 2010
(86) PCT No.: PCT/JP2010/000748

§ 371 Date: Aug. 3, 2011

(30) Foreign Application Priority Data
Apr. 27, 2009 (JP) 2009-108442

(51) Int. Cl. G01R 27/28; H01L 29/66

(52) U.S. Cl. 324/649; 257/253; 257/E29.166

(57) ABSTRACT

Provided is a chemical sensor requiring no ion-sensitive film. Specifically provided is a chemical sensor (1) for detecting a sample base material (19) to be detected in a sample, the chemical sensor (1) including: a sensor TFT (7) of sensor TFTs (7) each of which has a glass substrate (8) and, on the glass substrate (8), a gate electrode (10), a gate oxide film (11), a silicon layer (12), a source electrode (14), and a drain electrode (15), the silicon layer (12) having a channel region (18) at an opening portion between the source electrode (14) and the drain electrode (15); and extracting signal lines PAS₁ to PASₙ and a sensor signal amplifying and extracting circuit (24) that extract a leak current that is generated in the channel region (18).

### TECHNICAL FIELD

The present invention relates to a chemical sensor. More specifically, the present invention relates to a chemical sensor using a thin-film transistor.

### BACKGROUND ART

Conventionally, as a technique of detecting and measuring a chemical substance or a biological substance in a sample, a biosensor called an ISFET (Ion Sensitive FET) is known, for example. FIG. 6 is a cross-sectional view illustrating a conventional ISFET. The ISFET 100 has a configuration in which a gate electrode is eliminated from a normal MOSFET and a place where a channel 104 is provided is covered with an ion-sensitive film 106. In the ISFET 100, a specific ion to be detected in a sample solution 108 selectively reacts with the ion-sensitive film 106. This causes a change in a surface potential at a gate portion and accordingly a change in a drain current. A biosensor of the ISFET 100 detects this change in the drain current I_{d}.

Patent Literatures 1 and 2 describe other examples of the biosensor that uses the ISFET, namely, biosensors each of which uses a thin film device, such as a polysilicon transistor, as the ISFET. An ISFET array in which a plurality of ISFETs are two-dimensionally provided is also conventionally known. For example, Patent Literature 3 describes an ISFET array in which an influence of noise from switching operation is reduced.

### CITATION LIST

### Patent Literature 1

Japanese Patent Application Publication, Tokukai, No. 2002-296228 A (Publication Date: Oct. 9, 2002)

### Patent Literature 2

Japanese Patent Application Publication, Tokukai, No. 2002-296229 A (Publication Date: Oct. 9, 2002)

### Patent Literature 3

Japanese Patent Application Publication, Tokukai, No. 2000-55874 A (Publication Date: Feb. 25, 2000)

### SUMMARY OF INVENTION

### Technical Problem

As described above, the ISFET employs the ion-sensitive film so as to detect a specific ion. Due to this, different ion-sensitive films need to be used depending on the ion to be detected. This makes the IEFET disadvantageous in terms of costs, in an effort to satisfy needs to use the IEFET appropriately on various sample solutions.

The present invention is accomplished in view of the aforementioned problems. An object of the present invention is to provide a chemical sensor that needs no ion-sensitive film.

### Solution to Problem

In order to attain the object, a chemical sensor according to the present invention is a chemical sensor for detecting a substance to be detected in a sample, including: a thin-film transistor or thin-film transistors each of which has a substrate and, on the substrate, a gate electrode, a gate insulating layer, a semiconductor layer, a source electrode, and a drain electrode, the semiconductor layer having a channel region at an opening portion between the source electrode and the drain electrode; and a current extracting section for extracting a leak current that is generated in the channel region.

In this configuration, the chemical sensor includes: the thin-film transistor or the thin-film transistors each of which has the substrate and, on the substrate, the gate electrode, the gate insulating layer, the semiconductor layer, the source electrode, and the drain electrode; and the current extracting section for extracting the leak current. In the thin-film transistor, there is an opening between the source electrode and the drain electrode. The channel region is formed at the opening portion in the semiconductor layer. Due to this configuration, the substance to be detected in the sample can approach the channel region from the opening portion. When the substance to be detected in the sample reaches the opening portion and a charge distribution around the opening portion changes, there can be a change in the leak current in the channel region due to a back channel effect. The current extracting section can detect the change in the leak current by extracting the leak current. Thus, the chemical sensor according to the present invention can detect whether or not the substance to be detected in the sample is present, as the change in an intensity of the leak current. This makes it possible to detect the substance without providing the ion-sensitive film as in the conventional ISFET.

Here, the back channel effect denotes a phenomenon in which an electron hole or an electron is induced in the back channel due to ions or the like from outside.

The back channel denotes a path through which the leak current flows on the surface of the semiconductor layer at an opening portion between the source electrode and the drain electrode.

In order to attain the object, a detection method according to the present invention is a detection method for detecting a substance to be detected in a sample, including: bringing the sample into contact with a chemical sensor which includes a thin-film transistor and a current extracting section, the thin-film transistor having a substrate and, on the substrate, a gate electrode, a gate insulating layer, a semiconductor layer, a source electrode, and a drain electrode, the semiconductor layer having a channel region at an opening portion between the source electrode and the drain electrode, the current extracting section being for extracting a leak current that is generated in the channel region; extracting, by means of the current extracting section, the leak current that is generated when the sample is brought into contact with the chemical sensor; and detecting the substance by use of a change in an intensity of the extracted leak current.

In this configuration, the leak current that is generated depending on whether or not the substance to be detected in the sample is present is extracted and the change in the leak current is used so as to detect the substance to be detected. That is, whether or not the substance to be detected in the sample is present can be detected as the change in the intensity of the leak current. This makes it possible to detect the substance to be detected in the sample without using the ion-sensitive film.

### ADVANTAGEOUS EFFECTS OF INVENTION

As described above, the chemical sensor according to the present invention includes the thin-film transistor having the semiconductor layer and the current extracting section for extracting the leak current that is generated in the channel region in the semiconductor layer, the channel region being formed at the opening portion between the source electrode and the drain electrode. Therefore, the chemical sensor can detect whether or not the substance to be detected in the sample is present, as the change in the intensity of the leak current.

### BRIEF DESCRIPTION OF DRAWINGS

FIG. 1 is a block diagram of a chemical sensor according to the present invention.

FIG. 2 is a cross-sectional view of a sensor TFT included in the chemical sensor according to the present invention.

FIG. 3 illustrates a sensor circuit in the chemical sensor as illustrated in FIG. 1.

FIG. 4(a) is a cross-sectional view of the sensor TFT when no substance to be detected is present around the sensor TFT. FIG. 4(b) is a cross-sectional view of the sensor TFT when a substance to be detected is present around the sensor TFT. FIG. 4(c) is a characteristic graph showing a relation between a gate voltage and a drain current when the sensor TFT is in a state as illustrated in FIG. 4(a). FIG. 4(d) is a characteristic graph showing a relation between a gate voltage and a drain current when the sensor TFT is in a state as illustrated in FIG. 4(b).

FIG. 5 is a dihedral drawing showing an outer appearance of one embodiment of the chemical sensor according to the present invention.

FIG. 6 is a schematic cross-sectional view of a conventional ISFET sensor.

FIG. 7 is a plan view showing an outer appearance of another embodiment of the chemical sensor according to the present invention.

### DESCRIPTION OF EMBODIMENTS

[Chemical Sensor]

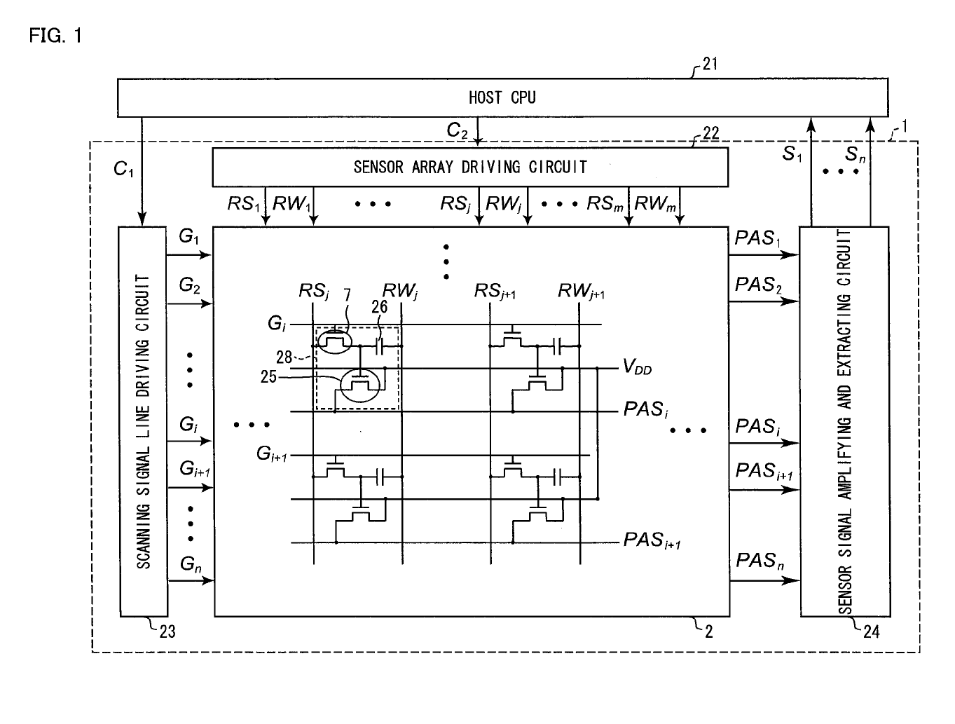

One embodiment of a chemical sensor according to the present invention will be described below with reference to FIGS. 1 to 5 and 7. In this embodiment, the chemical sensor is exemplified as a biosensor for measuring a sample in a biological sample.

FIG. 1 is a block diagram of a biosensor according to the present invention. As illustrated in FIG. 1, the biosensor 1 includes a sensor array 2, a sensor array driving circuit 22 and a scanning signal line driving circuit 23 that send a signal to the sensor array 2, and a sensor signal amplifying and extracting circuit (current extracting section) 24 for extracting a signal from the sensor array 2. The sensor array 2 includes a plurality of sensor TFTs (thin-film transistors) 7.

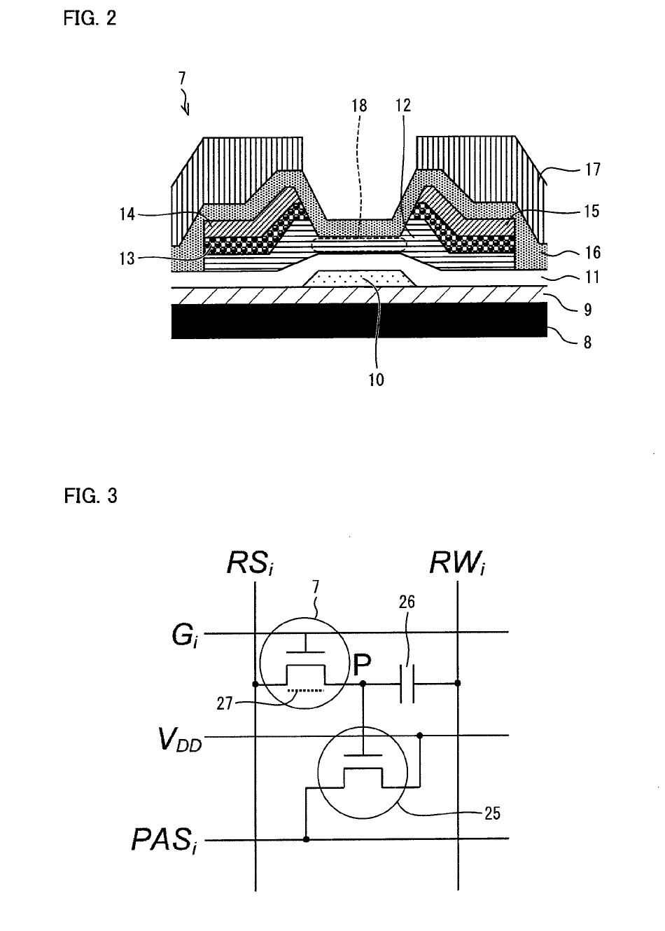

First, the sensor TFT 7 will be described with reference to FIG. 2, which is a schematic cross-sectional view of the sensor TFT 7. As illustrated in FIG. 2, the sensor TFT 7 includes a glass substrate (substrate) 8, a base coating film 9, a gate electrode 10, a gate oxide film (gate insulating layer) 11, a silicon layer (semiconductor layer) 12, an n+ layer 13, a source electrode 14, a drain electrode 15, a passivation film 16, and a shielding film 17. In the silicon layer 12, a channel region 18 is formed at an opening portion between the source electrode 14 and the drain electrode 15. A TFT that is conventionally used for driving a liquid crystal panel can be employed as the sensor TFT 7 having the above-described configuration.

Here, in the present embodiment, a back channel denotes a path on the silicon layer 12 side of an interface between the silicon layer 12 and the passivation film 16 at the opening portion between the source electrode 14 and the drain electrode 15, through which path a leak current flows. The region in which the back channel is formed is denoted as a back channel region.

In the case where the sample base material to be detected (substance to be detected) is electrically charged, the shielding film 17 electrically insulates, from the source electrode 14 and the drain electrode 15, the sample base material. The shielding film 17 may be an oxide film containing conductive particles homogenously or an oxide film having a very large thickness.

There is no particular limitation as to the passivation film 16, as long as the passivation film 16 is configured as one that is tolerant against a sample solution to be used for the detection. The passivation film 16 can be, for example, a SiNx film.

As described above, in the sensor TFT 7, the channel region 18 is formed at the opening portion between the source electrode 14 and the drain electrode 15. This allows the sample base material in the sample to approach the channel region 18. In the biosensor 1, a change in an intensity of the leak current is detected, which change can be caused by the approaching of the sample base material to the channel region 18. In this way, the detection of the change in the leak current allows detection of whether or not the sample base material is present. Here, the leak current that depends on whether or not the sample base material is present is generated through the following process. In a case where the sample base material contained in the sample solution is, for example, positively charged as a whole, the passivation film 16 is polarized as a whole in such a manner that the sample solution side of the passivation film 16 is negative and the silicon layer 12 side of the passivation film 16 is positive. The polarization of the passivation film 16 causes electrons to be attracted to a portion of the silicon layer 12 that is in the vicinity of the interface between the silicon layer 12 and the passivation film 16. This forms a channel (back channel). The formation of the back channel in the silicon layer 12 results in generation of the leak current. Here, the passivation film 16 preferably contains ionic impurities. For example, in a case where negative ionic impurities are contained in the passivation film 16, the presence of the positively-charged sample base material causes the negative ionic impurities in the passivation film 16 to be attracted toward the sample solution and distributed in the interface between the sample solution and the passivation film 16. This renders polarization in the passivation film 16 more intensive than that in a case where the passivation film contains no impurities. In this manner, it becomes possible to generate a bigger leak current.

That is, the biosensor 1 does not need the ion-sensitive film that is used in the conventional ISFET sensor.

Further, thinning the gate oxide film 11 leads to a larger drain current, thereby making it possible to improve measurement sensitivity.

Although the present embodiment employs the glass substrate 8 as the substrate of the sensor TFT 7, a substrate formed from a polymer material such as polycarbonate may also be used. The use of the polymer material allows the biosensor 1 to have a smaller weight. Also, the selection of the inexpensive material contributes to reduction in costs.

The gate electrode 10, the gate oxide film 11, the silicon layer 12, the n+ layer 13, the source electrode 14, the drain electrode 15, and the passivation film 16 may be formed from an organic material. For example, the gate electrode 10, the source electrode 14, and the drain electrode 15 may be formed using an organic conductor such as polyacetylene. The gate oxide film 11 and the passivation film 16 may be formed using an organic insulator such as polyimide. The silicon layer 12 and the n+ layer 13 may be formed using an organic semiconductor such as pentacene. The use of these materials for the formation allows the biosensor 1 to have a smaller weight. Also, the selection of the inexpensive materials contributes to reduction in costs. Further, the use of the substrate formed from the polymer material as described above contributes to a better flexibility of the sensor TFT 7 as a whole.

Next, an electric configuration of the biosensor 1 will be described below with reference to FIGS. 1 and 3.

As illustrated in FIG. 1, the sensor array 2 includes n-pieces of gate voltage signal lines G₁ to Gₙ, m-pieces of sensor reset signal lines RS₁ to RSₘ, m-pieces of sensor reading signal lines RW₁ to RWₘ, and (m×n)-pieces of sensor circuits 28. The sensor array 2 further includes n-pieces of extracting signal lines (current extracting section) PAS₁ to PASₙ. Here, m and n are each an integer equal to or greater than 1.

The gate voltage signal lines G₁ to Gₙ are arranged parallel to one another. The sensor reset signal lines RS₁ to RSₘ and the sensor reading signal lines RW₁ to RWₘ are arranged parallel to one another in such a manner that the sensor reset signal lines RS₁ to RSₘ and the sensor reading signal lines RW₁ to RWₘ orthogonally intersect the gate voltage signal lines G₁ to Gₙ.

Each of the sensor circuits 28 includes the sensor TFT 7, a preamplifier TFT 25 and a capacitor 26. The sensor circuits 28 are arranged in matrix on the sensor array 2. A gate terminal of the sensor TFT 7 is connected with the gate voltage signal line Gᵢ (i is an integer equal to or greater than 1 but not greater than n). A source terminal of the sensor TFT 7 is connected with the sensor reset signal line RSⱼ (j is an integer equal to or greater than 1 but not greater than m). A drain terminal of the sensor TFT 7 is connected with one of the electrodes of the capacitor 26. The other of the electrodes of the capacitor 26 is connected with the sensor reading signal line RWⱼ. A gate terminal of the preamplifier TFT 25 is connected with the drain terminal of the sensor TFT 7 at a contact point P. A power supply voltage V_{DD} is applied to a source terminal of the preamplifier TFT 25. A drain terminal of the preamplifier TFT 25 is connected with the extracting signal line PASᵢ.

The scanning signal line driving circuit 23 is a circuit that sends the gate voltage signals G₁ to Gₙ, which turns on and off the sensor TFT 7, to the respective sensor TFTs 7 on the sensor array 2. The sensor array driving circuit 22 is a circuit that sends sensor reading signals RW₁ to RWₘ and sensor reset signal RS₁ to RSₘ to the respective sensor TFTs 7 on the sensor array 2. The gate voltage signal G₁ to Gₙ can be controlled by means of a timing control signal C₁ from a host CPU 21. The sensor reading signals RW₁ to RWₘ and the sensor reset signals RS₁ to RSₘ can be controlled by means of a timing control signal C₂ from the host CPU 21.

The sensor signal amplifying and extracting circuit 24 extracts signals PAS₁ to PASₙ of the sensor TFTs 7 from the sensor array 2, amplifies the signals, and subsequently sends the signals to the host CPU 21.

[Detection Method]

Next, a description will be given on operations in the sensor circuit 28 in a detection method for detecting a sample base material in a sample by use of the biosensor 1. In the detection method, first, the sample is brought into contact with a vicinity of the channel region 18 of the sensor TFT 7. At this time, the back channel effect depending on whether or not the sample base material is present in the sample causes a change in intensity of the leak current in the back channel region of the TFT 7. The change in the intensity of the leak current leads to a change in the drain current. In the detection method, the leak current and the drain current are extracted and whether or not there is a change in the leak current is investigated, thereby detecting the sample base material in the sample.

In this Description, the wordings ‘change in the leak current’ and ‘change in an intensity of the leak current’ are used in an interchangeable manner.

FIG. 3 illustrates one of the sensor circuits 28 in the sensor array 2. For the purpose of detecting a change in the drain current that is modulated by the back channel effect, a predetermined voltage is applied to the sensor reading line RWᵢ and the sensor reset line RSᵢ, and the power supply voltage V_{DD} is applied to the source terminal of the preamplifier TFT 25. If the sample base material is present in the vicinity of the channel region 18 of the sensor TFT 7, the back channel 27 is formed in the sensor TFT 7. The back channel effect increases the leak current in the back channel 27, thereby increasing the drain current of the sensor TFT 7. When the drain current increases due to the increase in the leak current, a voltage at the contact point P decreases due to the flow of current. At this timing, a high voltage is applied to the sensor reading line RWᵢ so that the voltage at the contact point P increases and the gate voltage of the preamplifier TFT 25 exceeds a threshold. After this, the power supply voltage V_{DD} is applied to the source terminal side of the preamplifier TFT 25. When the power supply voltage V_{DD} is applied, the voltage at the contact point P is amplified at the preamplifier TFT 25, and an amplified voltage is outputted to the drain terminal side of the preamplifier TFT 25. In this manner, a change in the drain current and a change in the leak current in the sensor TFT 7, which changes are caused by the back channel effect, are detected based on a change in the signal outputted to the extracting signal line PASᵢ. The sensor signal amplifying and extracting circuit 24 sends the detection result to the host CPU 21, and the host CPU 21 carries out arithmetic processing. The host CPU 21 detects, through the arithmetic processing, the sample base material based on a change in the leak current.

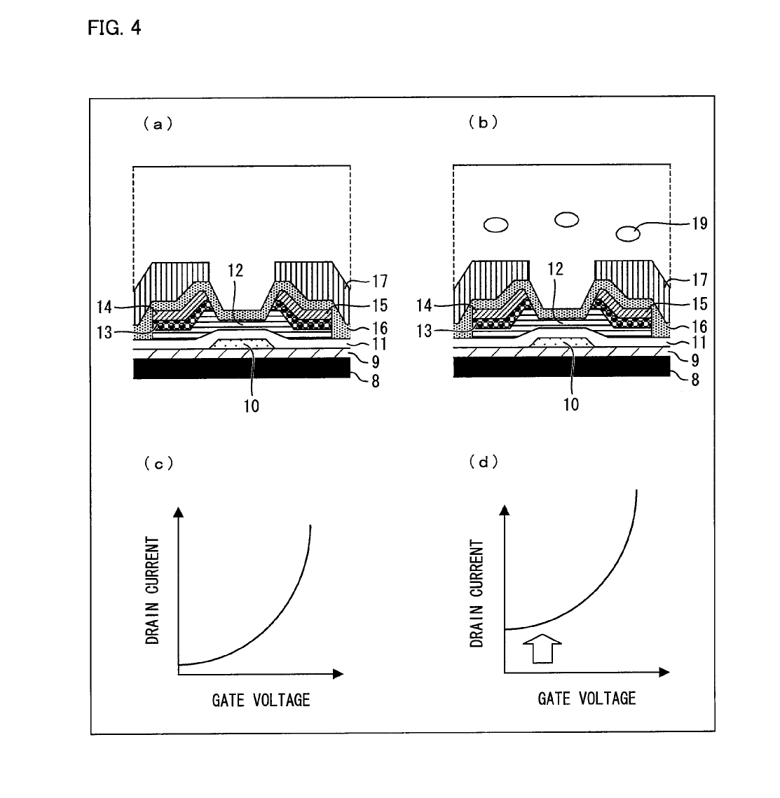

FIG. 4 shows a difference in the drain current, the difference being caused by whether or not the sample base material 19 is present. FIG. 4(a) illustrates the sensor TFT 7 in a case where the sample base material 19 to be detected is not present around the sensor TFT 7. FIG. 4(c) is a characteristic graph showing a relation of the gate voltage and the drain current in a case where the sensor TFT 7 is as illustrated by FIG. 4(a). FIG. 4(b) illustrates the sensor TFT 7 in a case where the sample base material 19 is present around the sensor TFT 7. FIG. 4(d) is a characteristic graph showing a relation between the gate voltage and the drain current in a case where the sensor TFT 7 is as illustrated by FIG. 4(b).

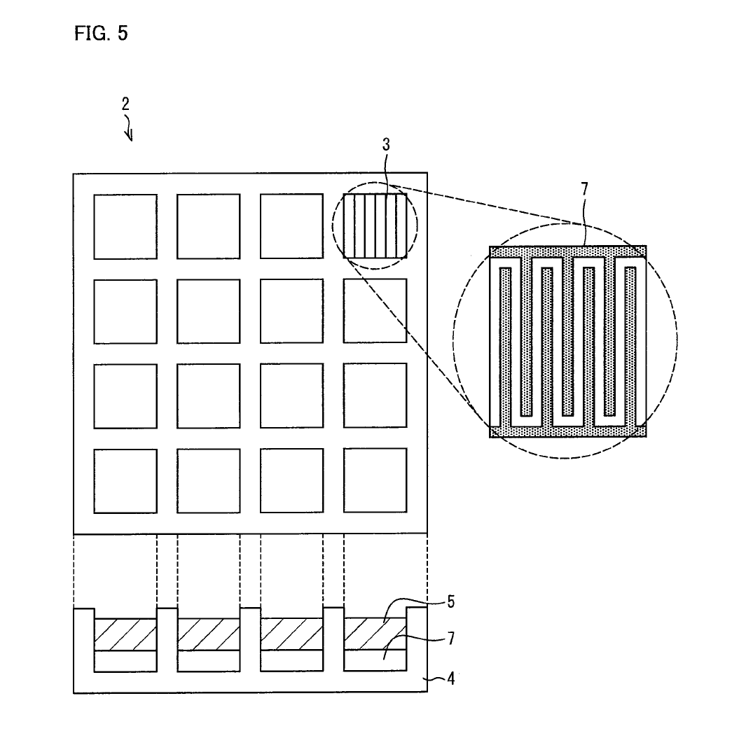

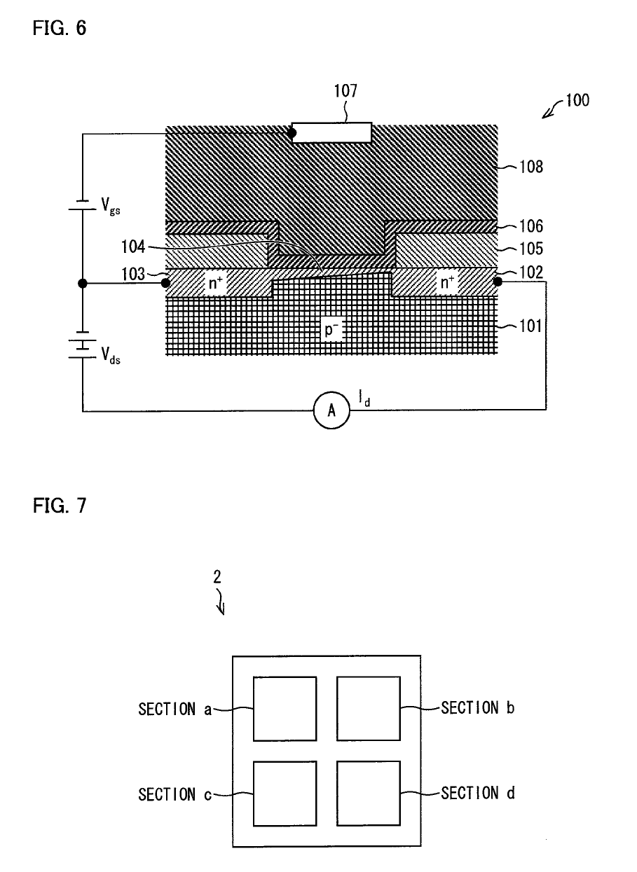

If the sample base material 19 is present, the back channel effect is generated in the sensor TFT 7, whereby the leak current increases. Due to this, as illustrated in FIG. 4(d), the drain current with respect to the same gate voltage increases as compared to the case where no sample base material 19 is present as illustrated in FIG. 4(c). That is, it is possible to detect an increase in the leak current based on an increase in the drain current, and to thereby detect a presence of the sample base material 19. Further, it becomes possible to distinguish different types of sample base materials 19 from each other by use of an amount of the leak current and a shape of the characteristic graph of the relation between the drain current and the gate voltage, or by use of a sensor array 2 to be described later with reference to FIG. 5, which sensor array 2 is a biosensor 1 in an array shape.

FIG. 5 is a schematic dihedral drawing illustrating the one embodiment of the biosensor 1. FIG. 5 shows a top view and a cross-sectional view. The biosensor 1 has a matrix structure in which partitions of a base 4 divide up the biosensor 1 into a plurality of square structures 3, thereby forming an array-shaped sensor array 2. On a bottom surface of each of the square structures 3, the sensor TFT 7 having the electrode 14 and the drain electrode 15 that are interleaved with each other is provided. The sample solution 5 is added to each of the square structures 3, and the detection is carried out by means of the sensor TFT 7. Here, sample solutions that are different from one another can be added to the respective square structures 3. This allows detection of a plurality of different samples to be carried out at the same time. Further, the use of the sensor array 2 as described above makes it possible to identify different types of sample base materials 19.

Here, the method for identifying the different types of sample base materials 19 will be described below with reference to FIG. 7, which is a plan view schematically illustrating the sensor array 2. For easy explanation, the sensor array 2 is exemplified as one that is made up of four sections, each of which has the sensor TFT 7. First, substances A to D are contained in sections a to d in such a manner that any one of the substances A to D is contained in any one of the sections a to d. Chemical reaction conditions of the substances A to D with the substances X and Y are known as shown in Table 1. The substances are ionized through the chemical reactions. The presence of the generated ions causes generation of the leak current in the sensor TFT 7.

TABLE 1

| | substance | substance | substance | substance |
|---|---|---|---|---|
| | A | B | C | D |
| reactive | YES | YES | NO | NO |
| with | | | | |
| substance | | | | |
| X | | | | |
| reactive | YES | NO | YES | NO |
| with | | | | |
| substance | | | | |
| Y | | | | |

In Table 1, ‘YES’ indicates a case where the substance causes a chemical reaction and ‘NO’ indicates a case where the substance causes no chemical reaction. Two of the sensor arrays 2 as described above are prepared (the same substance is contained in each pair of sections in the two sensor arrays, the pair of sections corresponding to each other between the two sensor arrays). The substance X is further added to one of the sensor arrays 2 and the substance Y is further added to the other of the sensor arrays 2. The addition of the substance X or Y causes the substances A to D to react in the manners as shown in Table 1. When the reactions occur, the leak currents are generated. Thus, by detecting the leak currents that are generated in the respective sections in the two sensor arrays 2, it becomes possible to determine which of the substances A to D is contained in the respective sections.

The method for distinguishing the types of the sample base materials is not limited to the use of the sensor array 2. For example, in a case where the substance A turns into a divalent ion through the reaction with the substance X and the substance B turns into a monovalent ion through the reaction with the substance Y, the ions that are generated through the reactions have different ion concentrations from each other. This results in a difference in an amount of carriers that are induced in the back channel and accordingly results in a difference in a magnitude of the leak current that is generated. Thus, by measuring the magnitudes of the leak currents, the types of the sample base materials can be identified without using the array-shaped biosensor 1.

There is no specific limitation as to the substance to be detected by the biosensor 1 according to the present invention. For example, the biosensor 1 can detect an ion contained in a sample solution. The biosensor 1 can also detect an ion that is generated through a chemical reaction between a substance contained in the sample and another substance, as described above.

When there is a difference in an ion concentration, there will be also a difference in an amount of polarized charges in the passivation film 16. This results in a difference in an amount of carriers that are induced in the back channel in the silicon layer 12, and accordingly in a difference in a magnitude of the leak current. That is, the difference in the concentration of the ions that are contained in the sample solution causes a difference in the back channel effect, and the difference in the back channel effect causes a change in the magnitude of the leak current.

Further, in a manner as described below, the method biosensor 1 can be applied to a DNA chip for detecting whether or not there is a target DNA based on whether or not there is hybridization. A complementary strand of the target DNA is caused to bind to the passivation film 16 at a position between or near the source electrode 14 and the drain electrode 15, or to the shielding film 17. The complementary strand thus bound is ionized. The ionization of the complementary strand is to be cancelled when the complementary strand and the target DNA together form a double strand. In this way, the ionization state in the vicinity of the back channel region changes depending on whether or not there is hybridization. This results in a change in the leak current. It should be noted that the binding of the complementary strand DNA to the passivation film 16 or the like, the ionization, or the like may be conducted based on a known conventional method.

As described above, the biosensor 1 according to the present invention detects the sample base material 19 by use of the back channel effect of the TFT. This eliminates the need of the ion-sensitive film and makes it possible to manufacture the sensor TFT 7 in conventional TFT steps that are employed in manufacturing a liquid crystal panel. Materials and processes to be used in the manufacturing are generally identical with those in the conventional TFT manufacturing steps. This makes it possible to secure the same levels of production amount and costs as those for a TFT portion of the conventional liquid crystal panel.

Further, the use of the back channel effect allows the gate voltage to be actively applied by the gate electrode 10 in the sensor TFT 7. This makes it possible to control the drain current.

Further, in the chemical sensor according to the present invention, the substrate is preferably formed from a polymer material.

This configuration makes it possible to further reduce a weight of the chemical sensor.

Further, in the chemical sensor according to the present invention, at least one of the gate electrode, the gate insulating layer, the semiconductor layer, the source electrode, and the drain electrode is preferably formed from an organic material.

This configuration makes it possible to further reduce a weight of the chemical sensor. Further, by forming all of the gate electrode, the gate insulating layer, the semiconductor layer, the source electrode, and the drain electrode, the chemical sensor can be made flexible.

In the chemical sensor according to the present invention, it is preferable that the thin-film transistors be arranged in array and be separated from one another through sectioning by means of partitions.

This configuration makes it possible to provide a plurality of different samples to the respective thin-film transistors. This allows detection of the plurality of samples to be carried out at the same time.

The present invention is not limited to the above-described embodiments but allows various modifications within the scope of the claims. In other words, any embodiment obtained by combining technical means appropriately modified within the scope of the claims will also be included in the technical scope of the present invention.

### INDUSTRIAL APPLICABILITY

The present invention can be employed in a medical field of analyzing a biological sample and other chemical substance.

### REFERENCE SIGNS LIST

1: biosensor (chemical sensor)
2: sensor array
7: sensor TFT (thin-film transistor)
8: glass substrate (substrate)
9: base coating film
10: gate electrode
11: gate oxide film (gate insulating layer)
12: silicon layer (semiconductor layer)
13: n+ layer
14: source electrode
15: drain electrode
16: passivation film
17: shielding film
18: channel region
19: sample base material (substance to be detected)
22: sensor array driving circuit
23: scanning signal line driving circuit
24: sensor signal amplifying and extracting circuit (current extracting section)
25: preamplifier TFT
27: back channel
28: sensor circuit
100: ISFET
101: substrate
102: drain electrode
103: source electrode
104: channel
105: protection and insulation film
106: ion-sensitive film
107: reference electrode
108: sample solution

1. A chemical sensor for detecting a substance to be detected in a sample, comprising:
a thin-film transistor or thin-film transistors each of which has a substrate and, on the substrate, a gate electrode, a gate insulating layer, a semiconductor layer, a source electrode, and a drain electrode, the semiconductor layer having a channel region at an opening portion between the source electrode and the drain electrode; and
a current extracting section for extracting a leak current that is generated in the channel region.

2. The chemical sensor according to claim 1, wherein the substrate is formed from a polymer material.

3. The chemical sensor according to claim 1, wherein at least one of the gate electrode, the gate insulating layer, the semiconductor layer, the source electrode, and the drain electrode is formed from an organic material.

4. The chemical sensor according to claim 1, wherein the thin-film transistors are arranged in array and are separated from one another through sectioning by means of partitions.

5. A detection method for detecting a substance to be detected in a sample, comprising:
bringing the sample into contact with a chemical sensor which includes a thin-film transistor and a current extracting section, the thin-film transistor having a substrate and, on the substrate, a gate electrode, a gate insulating layer, a semiconductor layer, a source electrode, and a drain electrode, the semiconductor layer having a channel region at an opening portion between the source electrode and the drain electrode, the current extracting section being for extracting a leak current that is generated in the channel region;
extracting, by means of the current extracting section, the leak current that is generated when the sample is brought into contact with the chemical sensor; and
detecting the substance by use of a change in an intensity of the extracted leak current.
